(19) United States
(12) Patent Application Publication
(10) Pub. No.: US 2026/0116049 A1
(43) Pub. Date: Apr. 30, 2026

(54) POLYMER FILM, LAMINATE, AND PRODUCTION METHOD OF LAMINATE

(71) Applicant: FUJIFILM Corporation, Tokyo (JP)

(72) Inventors: Yasuyuki Sasada, Kanagawa (JP); Miyoko Shibano, Kanagawa (JP)

(73) Assignee: FUJIFILM Corporation, Tokyo (JP)

(21) Appl. No.: 19/430,328

(22) Filed: Dec. 23, 2025

Related U.S. Application Data
(63) Continuation of application No. PCT/JP2024/020872, filed on Jun. 7, 2024.

(30) Foreign Application Priority Data
Jun. 30, 2023 (JP) 2023-108856

(51) Int. Cl. B32B 15/06; B32B 15/20; B32B 25/14; H05K 1/03

(52) U.S. Cl. CPC B32B 15/06; B32B 15/20; B32B 25/14; B32B 2250/03; B32B 2307/538; B32B 2307/54; B32B 2311/12; B32B 2457/08; H05K 1/036

(57) ABSTRACT

A production method of a laminate, including, in the following order: a step of disposing a metal substrate on at least one surface of a polymer film, the polymer film including a material a and a material b having different transition temperatures, including a layer B having an elastic modulus at 160° C. of 0.60 MPa or less, and having a dielectric loss tangent of 0.01 or less; a step of pressurizing at a temperature at which elastic moduli of the material a and the material b are each 0.60 MPa or more; a step of heating, at a pressure at which an absolute value of a pressure change rate from a pressure in the step of pressurizing is 10% or less, to a temperature at which the elastic modulus of the material a is less than 0.60 MPa and the elastic modulus of the material b is 0.60 MPa or more; a step of cooling to a temperature at which the elastic modulus of the material a is 0.60 MPa or more; and a step of unloading.

### CROSS-REFERENCE TO RELATED APPLICATIONS

This application is a continuation of International Application No. PCT/JP2024/020872, filed on Jun. 7, 2024, which claims priority from Japanese Patent Application No. 2023-108856, filed on Jun. 30, 2023. The entire disclosure of each of the above applications is incorporated herein by reference.

### BACKGROUND OF THE INVENTION

### 1. Field of the Invention

The present disclosure relates to a polymer film, a laminate, and a production method of a laminate.

### 2. Description of the Related Art

In recent years, frequencies used in communication equipment have become extremely high. In order to suppress transmission loss in a high frequency band, insulating materials used in a circuit board are required to have a lowered relative permittivity and a lowered dielectric loss tangent. A copper-clad laminated plate is suitably used as a member constituting a circuit board, and a polymer film is suitably used for producing the copper-clad laminated plate.

For example, JP2023-000377A discloses a laminate in which a coating film including powder consisting of a high-melting-point adhesive resin is laminated on at least one surface of a substrate film consisting of a polyether ether ketone (PEEK) resin. WO2022/163776A discloses a polymer film including a layer A, and a layer B provided on at least one surface of the layer A, in which the layer A includes a polymer having a dielectric loss tangent of 0.01 or less, the layer B includes an additive, and the layer B has an inflection point in a change in elastic modulus with a change in temperature or a change in deformation rate, or the elastic modulus is decreased under pressure.

### SUMMARY OF THE INVENTION

Typically, a copper-clad laminated plate is manufactured by laminating a copper foil on a surface of a polymer film. In addition, the wiring board is manufactured by superimposing a copper-clad laminated plate and a wiring base material such that a polymer film in the copper-clad laminated plate and the wiring base material are in contact with each other. In a case of manufacturing a wiring board, from the viewpoint of adhesiveness, it is required that the polymer film deforms by following the step formed on the surface of the wiring base material.

On the other hand, in a case where a polymer film having excellent step followability with respect to the wiring base material is used for the copper-clad laminated plate, interlayer peeling may occur in a reflow soldering step performed in a case of mounting an electronic component. Therefore, it has been required to achieve both excellent step followability with respect to the wiring base material and excellent adhesiveness during reflow soldering (that is, excellent heat resistance).

An object to be achieved by one embodiment of the present disclosure is to provide a polymer film having excellent step followability and heat resistance, a laminate, and a production method of a laminate.

The means for achieving the above-described objects include the following aspects.

<1>

A production method of a laminate, including, in the following order:
a step of disposing a metal substrate on at least one surface of a polymer film, the polymer film including a material a and a material b having different transition temperatures, including a layer B having an elastic modulus at 160° C. of 0.60 MPa or less, and having a dielectric loss tangent of 0.01 or less;
a step of pressurizing at a temperature at which elastic moduli of the material a and the material b are each 0.60 MPa or more;
a step of heating, at a pressure at which an absolute value of a pressure change rate from a pressure in the step of pressurizing is 10% or less, to a temperature at which the elastic modulus of the material a is less than 0.60 MPa and the elastic modulus of the material b is 0.60 MPa or more;
a step of cooling to a temperature at which the elastic modulus of the material a is 0.60 MPa or more; and
a step of unloading.
   <2>

The production method of a laminate according to <1>, in which a pressure in the step of heating is 2 MPa to 6 MPa.

<3>

The production method of a laminate according to <1> or <2>, in which, in the step of heating, heating is performed to a temperature of 170° C. to 260° C.

<4>

The production method of a laminate according to any one of <1> to <3>,
in which the polymer film further includes a layer A having an elastic modulus at 160° C. of more than 0.60 MPa, and
the production method further comprises a step of manufacturing the polymer film by disposing the layer B on at least one surface of the layer A.
   <5>

The production method of a laminate according to <4>,
in which the step of manufacturing the polymer film further includes
   a step of preparing a solution for forming a layer A by performing dispersion treatment with a bead mill, and
   a step of forming a film by using the solution for forming a layer A and a solution for forming a layer B.
      <6>

The production method of a laminate according to any one of <1> to <5>, in which the material a is an elastomer including a constitutional unit derived from styrene.

<7>

The production method of a laminate according to any one of <1> to <6>, in which the material a is at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

<8>

The production method of a laminate according to any one of <1> to <7>, in which the material b is at least one selected from the group consisting of a liquid crystal polymer, a polymerized substance of a compound having a cyclic aliphatic hydrocarbon group and a group having an ethylenically unsaturated bond, and a fluororesin.

<9>

The production method of a laminate according to any one of <1> to <8>, in which a content of the material b is 10% by mass to 30% by mass with respect to a total mass of the layer B.

<10>

A polymer film including:
a layer A; and
a layer B disposed on at least one surface of the layer A,
in which a surface roughness Rc of a surface of the layer A on a side where the layer B is disposed is more than 5 μm,
the layer B contains a material a having an elastic modulus at 260° C. of less than 0.10 MPa and a material b having an elastic modulus at 260° C. of 0.10 MPa or more, and has an elastic modulus at 160° C. of 0.60 MPa or less, and
a dielectric loss tangent is 0.01 or less.
   <11>

The polymer film according to <10>, in which the layer A has an elastic modulus at 160° C. of more than 0.60 MPa.

<12>

The polymer film according to <10> or <11>, in which the material a is an elastomer including a constitutional unit derived from styrene.

<13>

The polymer film according to any one of <10> to <12>, in which the material a is at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

<14>

The polymer film according to any one of <10> to <13>, in which the material b is at least one selected from the group consisting of a liquid crystal polymer, a polymerized substance of a compound having a cyclic aliphatic hydrocarbon group and a group having an ethylenically unsaturated bond, and a fluororesin.

<15>

A laminate including: the polymer film according to any one of <10> to <14>; and a metal layer or a metal wiring disposed on at least one surface of the polymer film.

<16>

The laminate according to <15>,
in which the laminate includes the layer A, the layer B, and the metal layer or the metal wiring in this order, and
a peel strength between the layer B and the metal layer or the metal wiring is 0.3 kN/m or more.

According to one embodiment of the present disclosure, a polymer film having excellent step followability and heat resistance, a laminate, and a production method of a laminate are provided.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, unless otherwise specified, the weight-average molecular weight (Mw) and the number-average molecular weight (Mn) in the present disclosure are molecular weights converted using polystyrene as a standard substance, measured by a gel permeation chromatography (GPC) analysis apparatus using a TSKgel SuperHM-H column (trade name, manufactured by Tosoh Corporation) with a solvent of pentafluorophenol (PFP)/chloroform at a mass ratio of 1/2, and detected with a differential refractometer.

The average particle diameter (for example, D50) of the particles in the present disclosure is measured using a laser diffraction/scattering-type particle size distribution analyzer. As a laser diffraction/scattering type particle diameter distribution analyzer, for example, LA-950V2 manufactured by Horiba, Ltd. is used.

### [Production Method of Laminate]

A production method of a laminate, includes, in the following order: a step of disposing a metal substrate on at least one surface of a polymer film, the polymer film including a material a and a material b having different transition temperatures, including a layer B having an elastic modulus at 160° C. of 0.60 MPa or less, and having a dielectric loss tangent of 0.01 or less (hereinafter, referred to as a “metal substrate disposing step”); a step of pressurizing at a temperature at which elastic moduli of the material a and the material b are each 0.60 MPa or more (hereinafter, referred to as a “pressurizing step”); a step of heating, at a pressure at which an absolute value of a pressure change rate from a pressure in the step of pressurizing is 10% or less, to a temperature at which the elastic modulus of the material a is less than 0.60 MPa and the elastic modulus of the material b is 0.60 MPa or more (hereinafter, referred to as a “heating step”); a step of cooling to a temperature at which the elastic modulus of the material a is 0.60 MPa or more (hereinafter, referred to as a “cooling step”); and a step of unloading (hereinafter, referred to as a “unloading step”).

As a result of intensive studies, the present inventors have found that, by adopting the above configuration, a laminate having excellent step followability and heat resistance can be provided.

The detailed mechanism that brings about the aforementioned effect is unclear, but is assumed to be as below.

In a case of manufacturing a multi-layer copper-clad laminated plate, the copper foil and the polymer film are laminated and then heat sealing is performed, but in this case, a part of the material contained in the polymer film is likely to flow upon heating. In a case of the heat sealing, in a case where the polymer film is heated without being covered, in a state of being in contact with a substance having a low surface energy such as air, or is heated in a state of not being pressurized, a part of the material that is likely to flow may move, and the material that is likely to flow may aggregate after the heat sealing, in the polymer film. In particular, such a movement or aggregation phenomenon was remarkable in a polymer film having a formulation having an elastic modulus at 160° C. of 0.60 MPa or less, which is low, and excellent step followability to the wiring board substrate. In the reflow soldering step performed in a case of mounting an electronic component, the polymer film is heated at a high temperature (for example, 260° C.), but in this case, it is considered that water inherent in the polymer film is supersaturated and diffuses, and a bubble nucleus is generated in an aggregated part of the material that is likely to flow. In the related art, growth of the bubble nucleus leading to foaming may cause peeling between the polymer film and the metal layer, or cohesive failure in the polymer film.

On the other hand, in the production method of a laminate according to the present disclosure, by including the metal substrate disposing step, the pressurizing step, the heating step, the cooling step, and the unloading step in this order, the movement of the material included in the polymer film is suppressed, and it is preferable that the pressurizing step is performed in a degassed state. It is considered that, since the material that is likely to flow does not aggregate, the generation or growth of the bubble nucleus is suppressed in the reflow soldering step, and as a result, peeling between the polymer film and the metal layer is suppressed. That is, the heat resistance is excellent.

On the other hand, JP2023-000377A and WO2022/163776A do not disclose that the metal substrate disposing step, the pressurizing step, the heating step, the cooling step, and the unloading step are performed in this order.

Hereinafter, each step of the production method of a laminate according to the present disclosure will be described.

### [Metal Substrate Disposing Step]

The metal substrate disposing step is a step of disposing a metal substrate on at least one surface of a polymer film including a material a and a material b having different transition temperatures and including a layer B having an elastic modulus at 160° C. of 0.60 MPa or less, in which a dielectric loss tangent is 0.01 or less.

### <<Layer B>>

The layer B includes a material a and a material b having different transition temperatures. The fact that the transition temperatures of the material a and the material b are different from each other can be confirmed by a differential scanning calorimetry apparatus.

The transition temperature may be a phase transition temperature or a glass transition temperature.

### <Material A>

The material a may be a low-molecular-weight compound or a high-molecular-weight compound.

From the viewpoint of step followability, the elastic modulus of the material a at 260° C. is preferably less than 0.10 MPa, and more preferably 0.05 MPa or less. The lower limit value of the elastic modulus of the material a at 260° C. is not particularly limited, and is, for example, 0.001 MPa.

In the present disclosure, the elastic modulus of the material a at 260° C. is measured by the following method.

A cross-sectional film sample prepared by oblique cutting with a microtome such that a thickness of a cross section is 50 μm is prepared.

Next, the elastic modulus of the material a at 260° C. is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

Among these, from the viewpoint of step followability, the material a is preferably a thermoplastic resin, a thermoplastic elastomer, an uncured or semi-cured product of a thermosetting resin, or an uncured or semi-cured product of a thermosetting elastomer.

Examples of the thermoplastic resin include a polyurethane resin, a polyester resin, a (meth)acrylic resin, a polystyrene resin, a fluororesin, a polyimide resin, a fluorinated polyimide resin, a polyamide resin, a polyamideimide resin, a polyether imide resin, a cellulose acylate resin, a polyurethane resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

Examples of the thermoplastic elastomer include an elastomer (polystyrene-based elastomer) containing a constitutional unit derived from styrene, a polyester-based elastomer, a polyolefin-based elastomer, a polyurethane-based elastomer, a polyamide-based elastomer, a polyacryl-based elastomer, a silicone-based elastomer, a polyimide-based elastomer, and the like. The thermoplastic elastomer may be a hydrogenated product.

Examples of the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrogenated products thereof.

Among these, from the viewpoint of dielectric loss tangent and step followability, the material a is preferably a thermoplastic elastomer, more preferably an elastomer containing a constitutional unit derived from styrene, and still more preferably at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

In particular, since the styrene-isobutylene-styrene block copolymer is difficult to soften at a high temperature (for example, 260° C.), it is advantageous in terms of heat resistance.

From the viewpoint of achieving both the step followability and the workability, a content of the material a is preferably 40% by mass to 95% by mass and more preferably 60% by mass to 90% by mass with respect to the total mass of the layer B.

The weight-average molecular weight of the material a is preferably 1,000 or more, more preferably 10,000 or more, and still more preferably 30,000 or more. The upper limit value of the weight-average molecular weight is, for example, 1,000,000.

The material a is preferably used as a powder in the production of a polymer film. In addition, the method of forming the material a into a powder more preferably includes a swelling step of swelling the material a with a liquid medium and a pulverization step of pulverizing the swollen material a.

<Material b>

The material b may be a low-molecular-weight compound or a high-molecular-weight compound.

From the viewpoint of step followability, the elastic modulus of the material b at 260° C. is preferably 0.10 MPa or more and more preferably 1.0 MPa or more. The upper limit value of the elastic modulus of the material b at 260° C. is not particularly limited, and is, for example, 1000 MPa.

In the present disclosure, the elastic modulus of the material b at 260° C. is measured by the following method.

A cross-sectional film sample prepared by oblique cutting with a microtome such that a thickness of a cross section is 50 μm is prepared.

Next, the elastic modulus of the material b at 260° C. is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

Examples of the material b include a thermosetting resin such as a liquid crystal polymer, a fluororesin, a polymerized substance of a compound having a cyclic aliphatic hydrocarbon group and a group having an ethylenically unsaturated bond, a polyphenylene ether and a modified product thereof, an aromatic polyether ketone, a phenol resin, an epoxy resin, a polyimide, a cyanate resin, a bismaleimide resin, and a triazine resin.

### —Liquid Crystal Polymer—

From the viewpoint of dielectric loss tangent, the material b preferably contains a liquid crystal polymer.

The type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the polymer melts at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) a liquid crystal polymer obtained by polycondensing a plurality of types of aromatic hydroxycarboxylic acids.
3) a liquid crystal polymer obtained by polycondensing (i) an aromatic dicarboxylic acid and (ii) at least one compound selected from the group consisting of an aromatic diol, an aromatic hydroxyamine, and an aromatic diamine.
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

The melting point of the liquid crystal polymer is preferably higher than 260° C., more preferably higher than 260° C. and 350° C. or lower, and still more preferably higher than 260° C. and 330° C. or lower.

In the present disclosure, the melting point is measured using a differential scanning calorimetry apparatus. For example, the measurement is performed using product name “DSC-60A Plus” (manufactured by Shimadzu Corporation). A temperature rising rate in the measurement is set to 10° C./minute.

The weight-average molecular weight of the liquid crystal polymer is preferably equal to or less than 1,000,000, more preferably 3,000 to 300,000, still more preferably 5,000 to 100,000, and particularly preferably 5,000 to 30,000.

The liquid crystal polymer preferably includes aromatic polyester amide from a viewpoint of further decreasing the dielectric loss tangent. Aromatic polyester amide is resin having at least one aromatic ring and having an ester bond and an amide bond. Among these, from the viewpoint of heat resistance, the aromatic polyester amide is preferably a fully aromatic polyester amide.

Aromatic polyester amide is preferably a crystalline polymer. The material b preferably includes a crystalline aromatic polyester amide. In a case where the aromatic polyester amide is crystalline, the dielectric loss tangent is further reduced.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature rising rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a constitutional unit represented by Formula 1, a constitutional unit represented by Formula 2, and a constitutional unit represented by Formula 3.

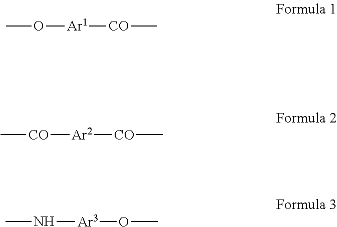

In Formula 1 to Formula 3, Ar¹, Ar², and Ar³ each independently represent a phenylene group, a naphthylene group, or a biphenylylene group.

Hereinafter, the constitutional unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a constitutional unit derived from p-hydroxybenzoic acid.

In a case where Ar¹ is a 2,6-naphthylene group, the unit 1 is, for example, a constitutional unit derived from 6-hydroxy-2-naphthoic acid.

In a case where Ar¹ is a 4,4′-biphenylylene group, the unit 1 is, for example, a constitutional unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a constitutional unit derived from terephthalic acid.

In a case where Ar² is an m-phenylene group, the unit 2 is, for example, a constitutional unit derived from isophthalic acid.

In a case where Ar² is a 2,6-naphthylene group, the unit 2 is, for example, a constitutional unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a constitutional unit derived from p-aminophenol.

In a case where Ar³ is a 4,4′-biphenylylene group, the unit 3 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other constitutional units other than the unit 1 to the unit 3. A content of other constitutional units is preferably 10% by mole or less and more preferably 5% by mole or less with respect to the total content of all constitutional units.

Aromatic polyester amide is preferably produced by subjecting a source monomer corresponding to the constitutional unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

### —Fluororesin—

From the viewpoint of heat resistance and mechanical strength, the material b may be a fluororesin.

In the present disclosure, the type of the fluororesin is not particularly limited, and a known fluororesin can be used.

Examples of the fluororesin include a homopolymer and a copolymer containing a constitutional unit derived from a fluorinated α-olefin monomer, that is, an α-olefin monomer containing at least one fluorine atom. In addition, examples of the fluororesin include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated α-olefin monomer include CF₂═CF₂, CHF═CF₂, CH₂═CF₂, CHCl═CHF, CClF═CF₂, CCl₂═CF₂, CClF═CClF, CHF═CC₁₂, CH₂═CClF, CC₁₂═CClF, CF₃CF═CF₂, CF₃CF═CHF, CF₃CH═CF₂, CF₃CH═CH₂, CHF₂CH═CHF, CF₃CF═CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a constitutional unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by the following formula.

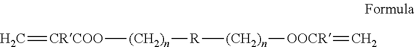

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

—Polymerized Substance of Compound which has Cyclic Aliphatic Hydrocarbon Group and Group Having Ethylenically Unsaturated Bond—

The material b may be a polymerized substance of a compound having a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### —Polyphenylene Ether—

The material b may be a polyphenylene ether.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

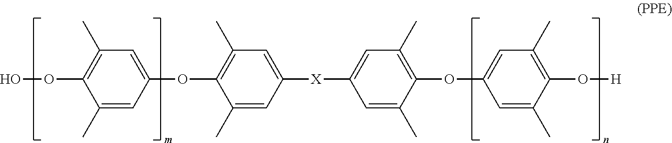

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

### —Aromatic Polyether Ketone—

The material b may be an aromatic polyether ketone.

The aromatic polyether ketone is not particularly limited, and a known aromatic polyether ketone can be used.

The aromatic polyether ketone is preferably a polyether ether ketone.

The polyether ether ketone is one kind of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

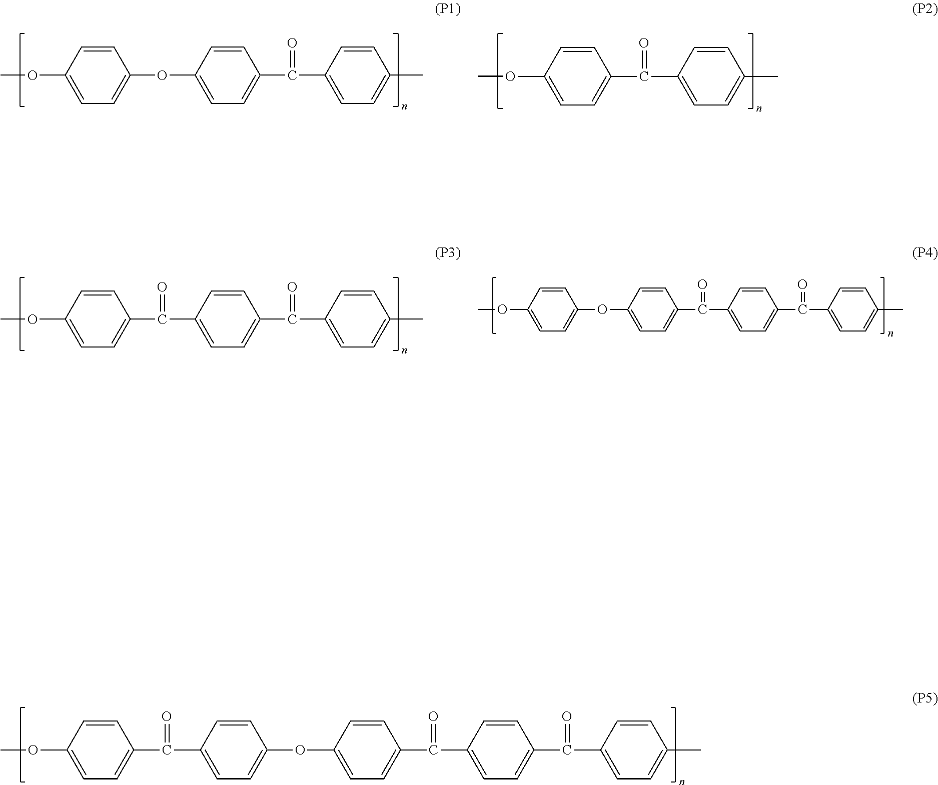

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

Among these, from the viewpoint of dielectric loss tangent, the material b is preferably at least one selected from the group consisting of a liquid crystal polymer, a polymerized substance of a compound having a cyclic aliphatic hydrocarbon group and a group having an ethylenically unsaturated bond, and a fluororesin, and more preferably an aromatic polyester amide.

In addition, the material b may have a particle shape. In a case where the material b has a particle shape, the material b may be organic particles or inorganic particles.

In a case where the layer B includes the material b in a particle shape, it is preferable that the layer B also includes the material b not in a particle shape.

Examples of the resin constituting the organic particles include polyethylene, polystyrene, urea-formalin filler, polyester, cellulose, acrylic resin, fluororesin, cured epoxy resin, crosslinked benzoguanamine resin, crosslinked acrylic resin, and a liquid crystal polymer. The resin constituting the organic particles may be one kind, or two or more kinds.

In addition, the organic particles may be fibrous, such as nanofibers, or may be hollow resin particles.

Among these, as the organic particles, from the viewpoint of the dielectric loss tangent and the step followability, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and crushing the liquid crystal polymer with a crusher or the like to obtain powdery liquid crystal.

The preferred aspect of the liquid crystal polymer constituting the liquid crystal polymer particles is the same as the preferred aspect of the above-described liquid crystal polymer.

From the viewpoint of dielectric loss tangent and step followability, the average particle diameter of the organic particles is preferably 5 nm to 20 μm and more preferably 100 nm to 10 μm.

Examples of the compound constituting the inorganic particles include boron nitride (BN), Al₂O₃, AlN, TiO₂, SiO₂, barium titanate, strontium titanate, aluminum hydroxide, and calcium carbonate. The compound constituting the inorganic particles may be one kind, or two or more kinds.

Among these, as the inorganic particles, from the viewpoint of dielectric loss tangent and step followability, metal oxide particles or fibers are preferable, silica particles, titania particles, or glass fibers are more preferable, and silica particles or glass fibers are particularly preferable.

From the viewpoint of dielectric loss tangent and step followability, the average particle diameter of the inorganic particles is preferably 5 nm to 20 μm, more preferably 10 nm to 10 μm, still more preferably 20 nm to 1 μm, and particularly preferably 25 nm to 500 nm.

From the viewpoint of heat resistance, a content of the material b is preferably 5% by mass to 60% by mass, more preferably 10% by mass to 40% by mass, and most preferably 10% by mass to 30% by mass with respect to the total mass of the layer B.

The layer B may contain other additives in addition to the material a and the material b.

Known additives can be used as other additives. Examples of other additives include a curing agent, a leveling agent, an antifoaming agent, an antioxidant, an ultraviolet absorber, a flame retardant, and a colorant.

In addition, the layer B may include a foaming agent that disappears by heating or decomposes by heating to release a gas. The foaming agent may be an organic foaming agent or an inorganic foaming agent.

Examples of the organic foaming agent include particles containing an acrylic resin as a main component, particles containing an ethyl cellulose resin as a main component, particles containing a butyral resin as a main component, nitrosamine compounds such as dinitrosopentamethylenetetramine (DPT), azo compounds such as azodicarbonamide (ADCA), and hydrazine compounds such as 4,4′-oxybisbenzenesulfonylhydrazide (OBSH) and hydrazodicarbonamide (HDCA).

Examples of the inorganic foaming agent include a hydrogen carbonate such as sodium hydrogen carbonate; a carbonate, and a combination of a hydrogen carbonate and an organic acid salt such as sodium citrate.

### <Physical Properties>

The elastic modulus of the layer B at 160° C. is 0.60 MPa or less, and preferably 0.50 MPa or less. In a case where the elastic modulus of the layer B at 160° C. is 0.60 MPa or less, the step followability is excellent. The lower limit value of the elastic modulus of the layer B at 160° C. is not particularly limited, but is 0.001 MPa from the viewpoint of suppressing the layer B from flowing and being extruded to the outside of the system during pressurization.

In the present disclosure, the elastic modulus of the layer B at 160° C. is measured by the following method.

A cross-sectional film sample prepared by oblique cutting with a microtome such that a thickness of a cross section is 50 μm is prepared.

Next, the elastic modulus of the layer B is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec. The elastic modulus is an average value of the elastic modulus measured at 20 points at any position of the cross section sample at 160° C.

From the viewpoint of step followability, the average thickness of the layer B is preferably 5 μm to 50 μm, more preferably 10 μm to 40 μm, and still more preferably 15 μm to 30 μm.

### <<Layer A>>

The polymer film used in the metal substrate disposing step preferably further includes a layer A having an elastic modulus at 160° C. of more than 0.60 MPa, in addition to the layer B.

In addition, it is preferable that the layer B is disposed on at least one surface of the layer A.

From the viewpoint of setting the dielectric loss tangent of the polymer film to 0.01 or less, the layer A preferably includes a polymer having a dielectric loss tangent of 0.01 or less.

The layer A may contain only one kind of polymer having a dielectric loss tangent of 0.01 or less, or may contain two or more kinds thereof.

From the viewpoint of the dielectric loss tangent of the polymer film, the dielectric loss tangent of the polymer having a dielectric loss tangent of 0.01 or less is preferably 0.005 or less and more preferably more than 0 and 0.003 or less.

Examples of the polymer having a dielectric loss tangent of 0.01 or less include thermoplastic resins such as a liquid crystal polymer, a fluororesin, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide, and a cyanate resin.

From the viewpoint of dielectric loss tangent of the polymer film, the polymer having a dielectric loss tangent of 0.01 or less is preferably a liquid crystal polymer. That is, the layer A preferably contains a liquid crystal polymer. A preferred aspect of the liquid crystal polymer is the same as the preferred aspect of the liquid crystal polymer which may be included in the layer B.

The layer A may contain a filler in addition to the polymer having a dielectric loss tangent of 0.01 or less. In a case where the layer A includes the filler, rigidity is improved, and wiring distortion and the like can be suppressed.

The filler may be a particulate filler or a fibrous filler, and may be inorganic particles or organic particles. Specific examples of the inorganic particles and the organic particles are as described above.

The layer A may contain only one, or two or more kinds of the fillers.

In a case where the layer A contains a filler, from the viewpoint of the dielectric loss tangent, the heat resistance, and the step followability of the laminate, the content of the filler is preferably 30% by mass to 95% by mass, more preferably 50% by mass to 90% by mass, and particularly preferably 60% by mass to 80% by mass with respect to the total mass of the layer A.

The layer A may contain an additive other than the above-described components.

A preferred aspect of the other additives which may be included in the layer A is the same as the preferred aspect of the other additives which may be included in the layer B.

In addition, the layer A may contain, as other additives, a resin other than the polymer having a dielectric loss tangent of 0.01 or less.

Examples of the resin other than the polymer having a dielectric loss tangent of 0.01 or less include thermoplastic resins other than liquid crystal polyester, such as polypropylene, polyamide, polyester other than liquid crystal polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the layer A is preferably 25 parts by mass or less, more preferably 10 parts by mass or less, and still more preferably 5 parts by mass or less with respect to 100 parts by mass of the content of the polymer having a dielectric loss tangent of 0.01 or less.

### <Physical Properties>

The elastic modulus of the layer A at 160° C. is preferably more than 0.60 MPa and more preferably 10 MPa or more. In a case where the elastic modulus of the layer A at 160° C. is more than 0.60 MPa, the layer B can be supported, and the step followability is excellent. The upper limit value of the elastic modulus of the layer A at 160° C. is not particularly limited, but is 1000 MPa from the viewpoint of suppressing wiring distortion and the like.

In the present disclosure, the elastic modulus of the layer A at 160° C. is measured by the following method.

A cross-sectional film sample prepared by oblique cutting with a microtome such that a thickness of a cross section is 50 μm is prepared.

Next, the elastic modulus of the layer A is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec. The elastic modulus is an average value of the elastic modulus measured at 20 points at any position of the cross section sample at 160° C.

The average thickness of the layer A is not particularly limited, but from the viewpoint of dielectric loss tangent of the laminate, heat resistance, and suppressing a wiring line distortion, the average thickness is preferably 5 μm to 90 μm, more preferably 10 μm to 70 μm, and particularly preferably 15 μm to 50 μm.

From the viewpoint of adhesiveness to the metal substrate, the polymer film preferably further includes a layer C in addition to the layer A and the layer B, and more preferably includes the layer B, the layer A, and the layer C in this order.

### <Layer C>

The layer C is preferably an adhesive layer. That is, the layer C is preferably a surface layer (outermost layer).

From the viewpoint of the dielectric loss tangent of the polymer film, the layer C preferably includes at least one polymer.

The preferred aspect of the polymer used in the layer C is the same as the preferred aspect of the polymer having a dielectric loss tangent of 0.01 or less, which is used in the layer A.

The polymer contained in the layer C may be the same as or different from the polymer contained in the layer A or the layer B, but from the viewpoint of adhesiveness between the layer A and the layer C, it is preferable that the polymer contained in the layer C is the same as the polymer contained in the layer A.

In addition, since the layer C is used to bond the metal layer and the layer A, it is preferable that the layer C contains an epoxy resin.

The epoxy resin is preferably a crosslinked product of a polyfunctional epoxy compound. The polyfunctional epoxy compound refers to a compound having two or more epoxy groups. The number of epoxy groups in the polyfunctional epoxy compound is preferably 2 to 4.

In particular, from the viewpoint of dielectric loss tangent of the laminate and adhesiveness with the metal layer, the layer C preferably contains aromatic polyester amide and an epoxy resin.

The layer C may contain a filler.

Preferred aspects of the filler which is used in the layer C are the same as the preferred aspects of the filler which is used in the layer A.

The layer C may contain an additive other than those described above.

Preferred aspects of other additives which are used in the layer C are the same as the preferred aspects of other additives which are used in the layer A, except as described below.

From the viewpoint of dielectric loss tangent of the laminate and adhesiveness with the metal, it is preferable that the average thickness of the layer C is smaller than the average thickness of the layer A.

From the viewpoint of dielectric loss tangent of the laminate and adhesiveness to the metal layer, a value of TA/TC, which is a ratio of the average thickness TA of the layer A to an average thickness TC of the layer C, is preferably more than 1, more preferably 2 to 100, still more preferably 2.5 to 20, and particularly preferably 3 to 10.

From the viewpoint of dielectric loss tangent of the laminate and adhesiveness to the metal layer, a value of TB/TC, which is a ratio of the average thickness TB of the layer B to the average thickness TC of the layer C, is preferably more than 1, more preferably 2 to 100, still more preferably 2.5 to 20, and particularly preferably 3 to 10.

Furthermore, from the viewpoint of dielectric loss tangent of the laminate and adhesiveness to the metal layer, the average thickness of the layer C is preferably 0.1 μm to 20 μm, more preferably 0.5 μm to 15 μm, still more preferably 1 μm to 10 μm, and particularly preferably 2 μm to 8 μm.

A method of measuring the average thickness of each layer in the polymer film is as follows.

The polymer film is cut along a plane perpendicular to a plane direction of the polymer film, thicknesses are measured at five or more points on a cross section thereof, and an average value thereof is defined as the average thickness.

### <Physical Properties of Polymer Film>

The dielectric loss tangent of the polymer film is 0.01 or less, preferably 0.005 or less and more preferably 0.003 or less. The lower limit value of the dielectric loss tangent is not particularly limited, but is, for example, 0.0005.

In the present disclosure, the dielectric loss tangent is measured by the following method.

The dielectric loss tangent is measured by a resonance perturbation method at a frequency of 10 GHz. A 10 GHz cavity resonator (“CP531” manufactured by Kanto Electronic Application & Development Inc.) is connected to a network analyzer (“E8363B” manufactured by Agilent Technologies, Inc.), a polymer film is inserted into the cavity resonator, and the measurement is performed from the change in resonance frequency before and after the insertion for 96 hours in an environment of a temperature of 25° C. and a humidity of 60% RH.

The average thickness of the polymer film is not particularly limited, but from the viewpoint of dielectric loss tangent and step followability, the average thickness is preferably 5 μm to 90 μm, more preferably 10 μm to 70 μm, and particularly preferably 15 μm to 50 μm.

The average thickness of the polymer film is measured at optional five sites using an adhesive film thickness meter, for example, an electronic micrometer (product name “KG3001A”, manufactured by Anritsu Corporation), and the average value of the measured values is defined as the average thickness of the polymer film.

It is preferable that the production method of a laminate according to the present disclosure further includes a step of manufacturing a polymer film including a layer A and a layer B disposed on at least one surface of the layer A (hereinafter, also referred to as a “polymer film manufacturing step”). As described above, the polymer film may include the layer C.

### <Polymer Film Manufacturing Step>

### (Film Formation)

A method for manufacturing a polymer film is not particularly limited, and a known method can be referred to.

Suitable examples of the film forming method include a co-casting method, a multilayer coating method, and a co-extrusion method. Among these, the film forming method is preferably a co-casting method.

In a case where a multilayer structure is manufactured by a co-casting method or a multilayer coating method, it is preferable to perform the co-casting method or the multilayer coating method using a solution for forming a layer A, a solution for forming a layer B, a solution for forming a layer C, and the like, which are obtained by dissolving or dispersing each component of each layer in a solvent.

In a case where the polymer film including the layer A and the layer B is manufactured, it is preferable that the polymer film manufacturing step includes a step of performing dispersion treatment with a bead mill to prepare a solution for forming a layer A, and a step of forming a film using the solution for forming a layer A and a solution for forming a layer B.

By performing the dispersion treatment with the bead mill, an effect of reducing and homogenizing the aggregates of the particles can be obtained.

A bead diameter of the beads used in the bead mill is preferably larger than an average particle diameter of the particles used for preparing the solution for forming a layer A. The bead diameter is, for example, 0.1 mm to 5 mm.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in the production step of the polymer film, in a case where the polymer film is manufactured by the co-casting method, the multilayer coating method, the co-extrusion method, or the like, a support may be used.

Examples of the support include a metal drum, a metal band, a glass plate, a resin film, and a metal foil. Among these, the support is preferably a metal drum, a metal band, or a resin film.

In addition, the support may have a surface treatment layer formed on the surface so that the support can be easily peeled off. Hard chrome plating, a fluororesin, or the like can be used as the surface treatment layer.

The average thickness of the support is not particularly limited, but is preferably 25 μm to 75 μm and more preferably 50 μm to 75 μm.

In addition, a method for removing at least a part of the solvent from a cast or applied film-like composition (a coating film) is not particularly limited, and a known drying method can be used.

### (Stretching)

In the manufacturing step of the polymer film, the stretching can be appropriately combined from the viewpoint of controlling molecular orientation and adjusting a thermal expansion coefficient and mechanical properties. The stretching method is not particularly limited, and a known method can be referred to, and the stretching method may be carried out in a solvent-containing state or in a dry film state. The stretching in the solvent-containing state may be carried out by gripping and stretching the laminate, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

### <Metal Substrate>

The metal substrate used in the metal substrate disposing step is, for example, a rolled metal foil formed by a rolling method or an electrolytic metal foil formed by an electrolytic method.

The metal substrate may be composed of a material known in the related art, and is preferably composed of silver or copper and more preferably composed of copper.

The metal substrate may be disposed on both surfaces of the polymer film. In this case, the two metal substrates may be metal substrates having the same material, thickness, and shape, or may be metal substrates having different materials, thicknesses, and shapes. From the viewpoint of adjusting the characteristic impedance, the two metal substrates may be metal substrates having different materials and thicknesses.

The average thickness of the metal substrate is not particularly limited, but is preferably 2 μm to 20 μm, more preferably 3 μm to 18 μm, and still more preferably 5 μm to 12 μm.

### [Pressurizing Step]

The pressurizing step is a step of pressurizing the material a and the material b at a temperature at which elastic moduli of the material a and the material b are each 0.60 MPa or more in a state of disposing the metal substrate on at least one surface of the polymer film. The pressurizing step is preferably performed in a degassed state in advance such that air is not mixed into the laminate and the movement or aggregation of a part of the material that is likely to flow is suppressed.

The temperature at which the elastic moduli of the material a and the material b are each 0.60 MPa or more is, for example, −10° C. to 150° C.

In the pressurizing step, the elastic moduli of the material a and the material b are each 0.60 MPa or more, and preferably 1.0 MPa or more. The upper limit value of the elastic moduli of the material a and the material b in the pressurizing step is not particularly limited, and is, for example, 100 MPa.

From the viewpoint of suppressing the flow of the material a, the pressure in the pressurizing step is preferably 1 MPa to 15 MPa, more preferably 2 MPa to 10 MPa, and still more preferably 2 MPa to 6 MPa.

In the pressurizing step, a holding time at the temperature at which the elastic moduli of the material a and the material b are each 0.60 MPa or more is, for example, 0.001 minutes to 10 minutes.

A method of pressurization in the pressurizing step is not particularly limited, and is performed, for example, using a laminator.

### [Heating Step]

The heating step is a step of heating the material a and the material b to a temperature at which the elastic modulus of the material a is less than 0.60 MPa and the elastic modulus of the material b is 0.60 MPa or more at a pressure at which an absolute value of a pressure change rate from a pressure in the pressurizing step is 10% or less.

The “absolute value of the pressure change rate from the pressure in the pressurizing step is 10% or less” means that, in a case of comparing the pressure in the pressurizing step with the pressure in the heating step, the absolute value of the change rate is 10% or less.

The pressure change rate is calculated by the following expression.

$$Pressure change rate ( \% ) = \{ ( Pressure in pressurizing step - Pressure in heating step ) / ( Pressure in pressurizing step ) \} \times 100$$

As the “pressure in the pressurizing step” in the above expression, the pressure in the pressurizing step immediately before the transition to the heating step is used.

In addition, as the “pressure in the heating step” in the above expression, the pressure in the heating step immediately after the transition to the heating step is used.

From the viewpoint of suppressing the flow of the material a, the pressure in the heating step is preferably 1 MPa to 15 MPa, more preferably 2 MPa to 10 MPa, and still more preferably 2 MPa to 6 MPa.

The temperature at which the elastic modulus of the material a is less than 0.60 MPa and the elastic modulus of the material b is 0.60 MPa or more is, for example, 160° C. to 260° C., and is preferably 170° C. to 260° C. from the viewpoint of suppressing the flow of the material a.

In the heating step, the elastic modulus of the material a is less than 0.60 MPa, and is preferably 0.30 MPa or less. The lower limit value of the elastic modulus of the material a in the heating step is not particularly limited, and is, for example, 0.01 MPa.

In the heating step, the elastic modulus of the material b is 0.60 MPa or more, and is preferably 1.0 MPa or more. The upper limit value of the elastic modulus of the material b in the heating step is not particularly limited, and is, for example, 1000 MPa.

In the heating step, a holding time at the temperature at which the elastic modulus of the material a is less than 0.60 MPa and the elastic modulus of the material b is 0.60 MPa or more is, for example, 1 minute to 200 minutes.

### [Cooling Step]

The cooling step is a step of cooling the material a to a temperature at which the elastic modulus of the material a is 0.60 MPa or more.

The temperature at which the elastic modulus of the material a is 0.60 MPa or more is, for example, −10° C. to 150° C.

In the cooling step, the elastic modulus of the material a after cooling is 0.60 MPa or more, and is preferably 1.0 MPa or more. The upper limit value of the elastic modulus of the material a after cooling is not particularly limited, and is, for example, 1000 MPa.

A method of cooling in the cooling step is not particularly limited, and examples thereof include air cooling and water cooling.

In the cooling step, it is preferable to cool the material a at a pressure at which an absolute value of a pressure change rate from a pressure in the heating step is 10% or less in order to unload in the unloading step described below.

From the viewpoint of suppressing the flow of the material a, the pressure in the cooling step is preferably 1 MPa to 15 MPa, more preferably 2 MPa to 10 MPa, and still more preferably 2 MPa to 6 MPa.

### [Unloading Step]

The unloading step is a step of releasing a state of being pressurized in a state of disposing the metal substrate on at least one surface of the polymer film. Specifically, the unloading step is a step of setting the pressure to 0 MPa.

### [Polymer Film]

The polymer film according to the present disclosure includes a layer A and a layer B disposed on at least one surface of the layer A, in which a surface roughness Rc of a surface of the layer A on a side where the layer B is disposed is more than 5 μm, the layer B includes a material a having an elastic modulus of less than 0.10 MPa at 260° C. and a material b having an elastic modulus of 0.10 MPa or more at 260° C., and has an elastic modulus of 0.60 MPa or less at 160° C. In addition, the dielectric loss tangent of the polymer film according to the present disclosure is 0.01 or less.

Preferred aspects of the layer A and the layer B are as described in the production method of the laminate.

The surface roughness Rc of the layer A on the side where the layer B is disposed is more than 5 μm, and is preferably 6 μm or more from the viewpoint of adhesiveness. In a case where the adhesiveness is improved, the heat resistance tends to be improved. In addition, from the viewpoint of improving the heat resistance of the layer A and the layer B, the surface roughness Rc is preferably 25 μm or less and more preferably 10 μm or less.

In the related art, the surface roughness Rc of the layer A on the side where the layer B is disposed has not been focused on from the viewpoint of adhesiveness between the layer A and the layer B.

Even in a case where the surface roughness Rc on the side of layer A on which layer B is disposed exceeds 5 μm, the polymer film according to the present disclosure can achieve both step followability and heat resistance by applying the laminate manufacturing method according to the present disclosure, as described above.

In a case where the layer B is disposed on one surface of the layer A, the surface roughness Rc of the layer A on the side where the layer B is disposed may be more than 5 μm, and the surface roughness Rc of the layer A on the side opposite to the side where the layer Bis disposed is not particularly limited.

In a case where the layer B is disposed on both surfaces of the layer A, the surface roughness Rc of both surfaces of the layer A is more than 5 μm.

In the present disclosure, the surface roughness Rc is measured by the following method.

The laminate of the layer A and the layer B is obliquely cut with a microtome to obtain a cross section. An average height Rc of the interface of the layer A on the layer B side is measured in accordance with JIS B0601:2013 (ISO 4287:1997). An evaluation length is 500 μm.

### [Laminate]

The laminate according to the present disclosure includes the polymer film according to the present disclosure and a metal layer or a metal wiring disposed on at least one surface of the polymer film according to the present disclosure.

Examples of a layer configuration of the laminate according to the present disclosure include the following aspects.
Aspect 1: metal layer/polymer film (layer A/layer B)
Aspect 2: metal layer/polymer film (layer C/layer A/layer B)
Aspect 3: metal layer (also referred to as a second metal layer)/polymer film (layer A/layer B)/metal layer
Aspect 4: metal layer (also referred to as a second metal layer)/polymer film (layer C/layer A/layer B)/metal layer

In the above-described aspects 1 to 4, the metal layer may be replaced with a metal wiring.

It is preferable that the laminate according to the present disclosure includes the layer B, the layer A, and the metal layer in this order. Specific examples thereof include the above-described aspects 1 and 2.

It is preferable that the laminate according to the present disclosure further includes a second metal layer, and includes the second metal layer, the layer A, the layer B, and the metal layer or the metal wiring in this order. Specific examples thereof include the above-described aspects 3 and 4.

The metal layer or the metal wiring may be made of a material known in the related art, and is preferably made of silver or copper and more preferably made of copper.

The metal layer or the metal wiring may be disposed on both surfaces of the polymer film. In this case, the two metal layers or metal wirings may be metal layers or metal wirings having the same material, thickness, and shape, or may be metal layers or metal wirings having different materials, thicknesses, and shapes. From the viewpoint of adjusting the characteristic impedance, the two metal layers or metal wirings may be metal layers or metal wirings having different materials and thicknesses.

In one embodiment, the metal layer is a rolled metal foil formed by a rolling method or an electrolytic metal foil formed by an electrolytic method.

The laminate according to the present disclosure includes the layer A, the layer B, and the metal layer or the metal wiring in this order, and a peel strength between the layer B and the metal layer or the metal wiring is preferably 0.3 kN/m or more, more preferably 0.5 kN/m or more, and still more preferably 0.7 kN/m to 5 kN/m.

In the present disclosure, the peel strength between the layer B and the metal layer or the metal wiring is measured by the following method.

A peeling test piece having a width of 1.0 cm is prepared from a laminate (laminate with a metal) of a polymer film and a metal layer or a metal wiring, the peeling test piece is fixed to a flat plate with a double-sided adhesive tape, and a strength (kN/m) in a case where the peeling test piece is peeled off at a rate of 50 mm/min according to the 90° method in conformity with JIS C 5016 (1994) is measured.

The average thickness of the metal layer is not particularly limited, but is preferably 2 μm to 20 μm, more preferably 3 μm to 18 μm, and still more preferably 5 μm to 12 μm.

In a case where the metal layer is a copper foil, the copper foil may be a copper foil with a carrier that is formed on a support (carrier) in a peelable manner.

As the carrier, a known carrier can be used. An average thickness of the carrier is not particularly limited, but is preferably 10 μm to 100 μm and more preferably 18 μm to 50 μm.

The metal layer may be a metal layer having a circuit pattern. It is also preferable that the metal layer is processed into a desired circuit pattern by, for example, etching, and a flexible printed circuit board is formed. The etching method is not particularly limited, and a known etching method can be used.

### EXAMPLES

Hereinafter, the present disclosure will be described in more detail with reference to Examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

Details of each material used for preparing the polymer film and the laminate are as follows.

### <<Layer B>>

### <Material A>

A1: frozen and pulverized product of hydrogenated styrene-isobutylene-styrene block copolymer (product name “SIBSTAR 103T-UL”, manufactured by Kaneka Corporation) swollen with N-methylpyrrolidone, average particle diameter of 5.0 μm (D50)
A2: Jet mill pulverized product of hydrogenated styrene-ethylene/butylene-styrene block copolymer (product name “TUFTEC M1913”, manufactured by Asahi Kasei Corporation), average particle diameter of 5.0 μm (D50)
   <Material b>
P1: Aromatic polyester amide prepared by the following preparation method

### —Synthesis of Aromatic Polyester Amide P1—

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature is raised from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off by-produced acetic acid and unreacted acetic anhydride, and maintained at 300° C. for 30 minutes. Thereafter, a content is taken out from the reactor and cooled to the room temperature. The obtained solid was pulverized by a pulverizer to obtain a powdered aromatic polyester amide Pla. A flow start temperature of the aromatic polyester amide Pla was 193° C. In addition, the aromatic polyester amide Pla was a fully aromatic polyester amide.

The aromatic polyester amide Pla was subjected to solid phase polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amideP1b. A flow start temperature of the aromatic polyester amide Plb was 220° C.

Aromatic polyester amide P1b is subjected to solid phase polymerization by raising the temperature from the room temperature to 180° C. for one hour and 25 minutes, next increasing the temperature from 180° C. to 255° C. over six hours and 40 minutes, and maintaining the temperature at 255° C. for five hours in a nitrogen atmosphere, and then, is cooled, and powdered aromatic polyester amide P1 is obtained.

A flow start temperature of the aromatic polyester amide P1 was 302° C. A melting point of aromatic polyester amide P1 was measured using a differential scanning calorimetry apparatus, and the result was 311° C. The dielectric loss tangent of the aromatic polyester amide P1 was 0.003.

### <<Layer A>>

### <Polymer>

Aromatic polyester amide P1 described above
LCP: LCP film used as film A3 described below

### <Filler>

F1: Liquid crystal polymer particles prepared by production method described below

### —Synthesis of Liquid Crystal Polymer Particles F1—

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst were put in a reactor including a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. The temperature was raised from room temperature to 150° C. over 15 minutes while stirring in a nitrogen gas stream, and refluxing was performed at 150° C. for 2 hours.

Next, the temperature was raised from 150° C. to 310° C. over 5 hours while distilling off by-produced acetic acid and unreacted acetic anhydride, and a polymerized substance was cooled to room temperature. An obtained polymerized substance increases in temperature from the room temperature to 295° C. over 14 hours, and is subjected to solid phase polymerization at 295° C. for one hour. After the solid phase polymerization, the mixture was cooled to room temperature over 5 hours.

The obtained liquid crystal polyester was pulverized using a jet mill (“KJ-200” manufactured by KURIMOTO LTD.) to obtain liquid crystal polymer particles F1. The liquid crystal polymer particles F1 had a median diameter (D50) of 7 μm, a dielectric loss tangent of 0.0007, and a melting point of 334° C.

### <Copper Foil>

M1: copper foil on which a layer C having a thickness of 3 μm was formed on a treated surface side by the following method, product name “CF-T9DA-SV-18”, manufactured by FUKUDA METAL FOIL & POWDER CO., LTD., average thickness: 18 μm

### —Formation of Layer C—

8 parts by mass of aromatic polyester amide P1 was added to 92 parts by mass of N-methylpyrrolidone, and the mixture was stirred at 140° C. for 4 hours in a nitrogen atmosphere to obtain a solution of aromatic polyester amide P1 (concentration of solid contents: 8% by mass).

0.04 parts by mass of an aminophenol-type epoxy resin (product name “jER630”, manufactured by Mitsubishi Chemical Corporation) was mixed with 9.96 parts by mass of the solution of the aromatic polyester amide P1 to prepare a solution.

The obtained solution was applied onto the treated surface of the copper foil with a bar coater and dried at 40° C. for 4 hours to remove the solvent from the coating film, thereby obtaining a copper foil forming the layer C with a thickness of 3 μm.
M2: product name “MT18FL”, manufactured by Mitsui Mining & Smelting Co., Ltd., average thickness: 1.5 μm, with 18 μm carrier foil
M3: product name “CF-T49A-DS-18”, manufactured by Fukuda Metal Foil & Powder Co., Ltd., average thickness: 18 μm

### Examples 1 to 14 and Comparative Examples 1 to 5

The laminate was produced by the following method. In Examples 1 to 14, steps 1 to 4 in Table 3 correspond to the pressurizing step, the heating step, the cooling step, and the unloading step, respectively.

In order to produce the polymer film, a solution for forming a layer A and a solution for forming a layer B were prepared.

### —Preparation of Solution for Forming Layer A—

As shown in Table 1, the solution for forming a layer A was prepared by a mixing method A or a mixing method B.

### (1) Mixing Method A

The polymer and the filler shown in Table 1 were mixed at the contents (mass %) shown in Table 1, N-methylpyrrolidone was added thereto, and the concentration of solid contents was adjusted to 25% by mass, and the mixture was stirred with a magnetic stirrer for 10 hours to obtain a solution for forming a layer A.

### (2) Mixing Method B

The polymer and the filler shown in Table 1 were mixed at the contents (mass %) shown in Table 1, and N-methylpyrrolidone was added thereto, and the concentration of solid contents was adjusted to 25% by mass.

The mixture was treated with zirconia beads (D50=1 mm) for 30 minutes using a bead mill (manufactured by ASIZAWA FINE TECH Co., Ltd., Lab Star Mini MGF015) to obtain a solution for forming a layer A.

### —Preparation of Solution for Forming Layer B—

The material a and the material b shown in Table 1 were mixed together at the contents (% by mass) shown in Table 1, N-methylpyrrolidone was added thereto to adjust the concentration of solid contents to 20% by mass, and a solution for forming a layer B was obtained.

### [Production of Polymer Film Having Copper Layer (Single-Sided Copper-Clad Laminated Plate)]

### —Film 1 and 2—

### (Production of Films A1 and A2)

The solution for forming a layer A corresponding to the films 1 and 2 shown in Table 1 was fed to a slot-die coater equipped with a slide coater, and applied onto the treated surface of the copper foil M1 by adjusting the flow rate such that the film thickness was 20 μm. The solvent was removed from the coating film by drying at 40° C. for 4 hours. Further, the temperature was raised from room temperature (25° C.) to 300° C. at 1° C./min in a nitrogen atmosphere. The laminate (films A1 and A2) on which the layer A was formed on the copper foil was obtained by performing a heat treatment of holding at 300° C. for 2 hours.

### (Production of Film B)

The solution for forming a layer B corresponding to the films 1 and 2 shown in Table 1 was fed to a slot-die coater equipped with a slide coater, and applied onto the support by adjusting the flow rate such that the film thickness was 30 μm. The solvent was removed from the coating film by drying at 40° C. for 4 hours. Further, the temperature was raised from room temperature (25° C.) to 300° C. at 1° C./min in a nitrogen atmosphere. The laminate (film B) on which the layer B was formed on the support was obtained by performing a heat treatment of holding at 300° C. for 2 hours. As the support, a fluororesin film (product name “NITOFLON #900UL”, manufactured by Nitto Denko Corporation, average thickness: 50 μm) was used.

### (Production of Films 1 and 2)

The surface of each of the films A1 and A2 on the layer A side and the surface of the film B on the layer B side were superimposed on each other, and a laminating treatment was performed for 1 minute under conditions of 140° C. and a laminating pressure of 0.4 MPa using a laminator (product name “Vacuum Laminator V-130”, manufactured by Nikko-Materials Co., Ltd.) to obtain a laminate in which the copper foil, the layer A, the layer B, and the support were laminated in this order. The support on the layer B side was peeled off to obtain a laminate (single-sided copper-clad laminated plate) in which the copper foil, the layer A, and the layer B were laminated in this order.

### —Film 3—

As the film A3, an LCP film (product name “VECSTAR CTQ”, manufactured by Kuraray Co., Ltd., average thickness: 50 μm) was used, and the treated surface side of the copper foil M3 was laminated with a thermal compression machine at 300° C. to obtain a laminate (film A3) on which the layer A was formed on the copper foil.

The surface of each of the films A3 on the layer A side and the surface of the film B on the layer B side were superimposed on each other, and a laminating treatment was performed for 1 minute under conditions of 140° C. and a laminating pressure of 0.4 MPa using a laminator (product name “Vacuum Laminator V-130”, manufactured by Nikko-Materials Co., Ltd.) to obtain a laminate in which the copper foil, the layer A, the layer B, and the support were laminated in this order. The support on the layer B side was peeled off to obtain a laminate (single-sided copper-clad laminated plate) in which the copper foil, the layer A, and the layer B were laminated in this order.

### —Film 4 to 10—

The obtained solution for forming a layer A and the solution for forming a layer B were fed to a slot-die coater equipped with a slide coater, and applied onto the treated surface of the support shown in Table 1 by adjusting the flow rate such that the film thickness was as shown in Table 1. The solvent was removed from the coating film by drying at 40° C. for 4 hours. Further, the temperature was raised from room temperature (25° C.) to 300° C. at 1° C./min in a nitrogen atmosphere. The laminate (single-sided copper-clad laminated plate) in which the copper foil, the layer A, and the layer B were laminated in this order was obtained by performing a heat treatment of holding at 300° C. for 2 hours.

### [Production of Four-Layered Copper-Clad Laminated Plate]

The carrier copper foil was peeled off in advance from the laminate using the film 7.

The produced films 1 to 10 were used to superimpose the films on each other such that the layer B and the copper foil were in contact with each other. Furthermore, the surface of the layer B of the outermost film and the copper foil shown in Table 3 were superimposed on each other. As a result, a laminate in which “copper foil, layer A, layer B”/“copper foil, layer A, layer B”/“copper foil, layer A, layer B”/“copper foil, layer A, layer B”/copper foil were laminated in this order was obtained.

A four-layered copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.).

Subsequently, using a thermal compression machine (product name “MP-SNL”, manufactured by Toyo Seiki Seisaku-sho, Ltd.), the obtained precursor of the double-sided copper-clad laminated plate was subjected to the steps 1 to 4 shown in Table 3 and heat-sealed to prepare a four-layered copper-clad laminated plate.

In Example 14, a four-layered copper-clad laminated plate was produced by heat sealing in a degassed state using a vacuum press device (product name “High temperature-compatible vacuum press device for PCB forming”, manufactured by Kitagawa Seiki Co., Ltd.) instead of the thermal compression machine.

### [Preparation of Wiring Board]

—Production of Base Material a with Wiring Patterns—

A copper foil (product name “CF-T9DA-SV-18”, average thickness of 18 μm, manufactured by Fukuda Metal Foil & Powder Co., Ltd.) and a liquid crystal polymer film (product name “CTQ-50”, average thickness of 50 μm, manufactured by Kuraray Co., Ltd.) as a base material were produced. The copper foil, the base material, and the copper foil were laminated in this order such that the treated surface of the copper foil was in contact with the base material. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained double-sided copper-clad laminated plate precursor was thermally compression-bonded for 10 minutes under conditions of 300° C. and 4.5 MPa to prepare a double-sided copper-clad laminated plate.

In Example 14, a double-sided copper-clad laminated plate was produced by thermocompression-bonding in a degassed state using a vacuum press device (product name “High temperature-compatible vacuum press device for PCB forming”, manufactured by Kitagawa Seiki Co., Ltd.) instead of the thermal compression machine.

The copper foils on both surfaces of the above-described double-sided copper-clad laminated plate were roughened, and a dry film resist was bonded thereto. The exposure was performed such that the wiring patterns remained, etching was performed after development, and the dry film was further removed to produce a substrate A with wiring patterns in which the line/space including the ground line and the three pairs of signal lines on both sides of the substrate was 100 μm/100 μm. A length of the signal line was 50 mm, and a width of the signal line was set such that characteristic impedance was 50Ω.

—Production of Base Material B with Wiring Pattern—

A copper foil (product name “MT18FL”, average thickness: 1.5 μm, with carrier copper foil (thickness: 18 μm), manufactured by Mitsui Mining & Smelting Co., Ltd.) and a liquid crystal polymer film (product name “CTQ-50”, average thickness: 50 μm, manufactured by Kuraray Co., Ltd.) as a base material were produced. The copper foil and the substrate were laminated in this order such that the treated surface of the copper foil was in contact with the substrate. A single-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained precursor of the single-sided copper-clad laminated plate was heat-sealed for 10 minutes under the conditions of 300° C. and 4.5 MPa to prepare a single-sided copper-clad laminated plate.

In Example 14, a single-sided copper-clad laminated plate was produced by heat sealing in a degassed state using a vacuum press device (product name “High temperature-compatible vacuum press device for PCB forming”, manufactured by Kitagawa Seiki Co., Ltd.) instead of the thermal compression machine.

The carrier copper foil on the surface opposite to the substrate of the single-sided copper-clad laminated plate was peeled off, the exposed surface of the 1.5 μm copper foil was roughened, and a dry film resist was bonded. After performing the pattern exposure and the development, a region where the resist pattern was not disposed was subjected to a plating treatment. Further, the dry film resist was peeled off, and copper exposed in the peeling step was removed by flash etching to prepare a substrate B with wiring patterns having a line/space of 20 μm/20 μm.

### —Production of Wiring Board—

The produced substrate with wiring patterns was overlaid on the layer B side of the produced single-sided copper-clad laminated plate, and a heat press was performed for 1 hour under the conditions of 160° C. and 4 MPa to obtain a wiring board.

In the obtained wiring board, wiring patterns (a ground line and a signal line) were buried, and in a case where the substrate A with wiring patterns was used, the thickness of the wiring patterns was 18 μm, and in a case where the substrate B with wiring patterns was used, the thickness of the wiring patterns was 12 μm.

The produced polymer film and wiring board were measured and evaluated as shown below, and the results are shown in Tables 1 and 2.

### <<Measuring Method>

### [Elastic Modulus of Layer a and Layer B at 160° C.]

The cross section of the double-sided copper-clad laminated plate was exposed with a cryomicrotome. Next, the layer A and the layer B were specified, and the elastic moduli of the layer A and the layer B at 160° C. were measured as an indentation elastic modulus using a nanoindentation method. The indentation elastic modulus was measured by using a microhardness meter (product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec. The elastic modulus was an average value of the elastic modulus measured at 20 points at any position of the cross section sample at 160° C.

[Elastic Modulus of Material a]

The cross section of the double-sided copper-clad laminated plate was exposed with a cryomicrotome. Next, the material a in the layer B was specified, and the elastic modulus of the material a was measured as an indentation elastic modulus using a nanoindentation method. The indentation elastic modulus was measured by using a microhardness meter (product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

[Elastic Modulus of Material b]

The cross section of the double-sided copper-clad laminated plate was exposed with a cryomicrotome. Next, the material b in the layer B was specified, and the elastic modulus of the material b was measured as an indentation elastic modulus using a nanoindentation method. The indentation elastic modulus was measured by using a microhardness meter (product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

Table 2 shows elastic moduli of the material a and the material b at 25° C., 40° C., 100° C., 160° C., 230° C., and 260° C.

In Table 2, “≥0.6” means that the elastic modulus is 0.6 MPa or more. “<0.6” means that the elastic modulus is less than 0.6 MPa.

### [Surface Roughness Rc]

The surface roughness Rc of the layer A on the side where the layer B was disposed was measured by exposing the cross section of the double-sided copper-clad laminated plate with a cryomicrotome, extracting the interface of the layer A on the layer B side with an optical microscope, and measuring an average height Rc in accordance with JIS B0601 2001. An evaluation length was 500 μm.

### [Dielectric Loss Tangent]

The copper foil of the double-sided copper-clad laminated plate was removed with an aqueous solution of ferric chloride, and the polymer film obtained by washing with pure water and drying was used for measurement.

The dielectric loss tangent was measured by a resonance perturbation method at a frequency of 10 GHz. A 10 GHz cavity resonator (“CP531” manufactured by Kanto Electronic Application & Development Inc.) was connected to a network analyzer (“E8363B” manufactured by Agilent Technologies, Inc.), a polymer film was inserted into the cavity resonator, and the dielectric loss tangent of the polymer film was measured from a change in resonance frequency before and after the insertion for 96 hours in an environment of a temperature of 25° C. and a humidity of 60% RH.

### <<Evaluation Method>>

### [Step Followability]

The wiring board was cut along the thickness direction with a microtome, and a cross section was observed with an optical microscope. The length L1 of the gap generated in the in-plane direction between the layer B and the wiring pattern was measured. The average value of the results at 10 sites was calculated. The evaluation standards are as follows.
A: No gap was recognized.
B: The average value of L1 was less than 0.5 μm.
C: The average value of L1 was 0.5 μm or more and less than 1 μm.
D: The average value of L1 was 1 μm or more.

### [Peel Strength]

The metal layer of the produced double-sided copper-clad laminated plate was subjected to electrolytic plating such that the thickness was 50 μm. The support side was fixed to a flat plate with a double-sided adhesive tape, and the metal layer was peeled off from the double-sided copper-clad laminated plate at a rate of 50 mm/min by a 90° method in accordance with JIS C 5016 (1994) in an environment of 25° C. and a relative humidity of 50% to measure a peel strength (kN/m) between the layer B and the metal layer.

### [Heat Resistance]

The prepared four-layered copper-clad laminated plate was cut out to a size of 30 mm×30 mm and used as an evaluation sample. The evaluation sample was treated in a constant temperature and humidity tank at a temperature of 85° C. and a relative humidity of 85% for 168 hours. Thereafter, the evaluation sample was placed in an oven set to 260° C. and heated for 15 minutes. The evaluation sample after heating was cut with a razor blade, the cross section was observed with an optical microscope, and the peeling state was visually evaluated.
A: No peeling was recognized between the layer B and the copper foil.
B: Peeling was recognized between the layer B and the copper foil with a width of 0.5 mm or less.
C: peeling was recognized between the layer B and the copper foil with a width of more than 0.5 mm and 1 mm or less.
D: peeling was recognized between the layer B and the copper foil with a width of more than 1 mm.

TABLE 1

| | Layer B | | | | | | Layer A | | |
|---|---|---|---|---|---|---|---|---|---|
| | Material a | | Material b | | | Elastic | Polymer | | |
| | | Contents | | Contents | | modulus | | Contents | |
| | | [% by | | [% by | Thickness | at 160° C. | | [% by | Additive |
| | Type | mass] | Type | mass] | [μm] | [MPa] | Type | mass] | Type |
| Film 1 | A1 | 70 | P1 | 30 | 30 | 0.48 | P1 | 25 | F1 |
| Film 2 | A1 | 70 | P1 | 30 | 30 | 0.48 | P1 | 100 | — |
| Film 3 | A1 | 70 | P1 | 30 | 30 | 0.48 | LCP | 100 | — |
| Film 4 | A1 | 70 | P1 | 30 | 30 | 0.48 | P1 | 25 | F1 |
| Film 5 | A1 | 70 | P1 | 30 | 30 | 0.48 | P1 | 25 | F1 |
| Film 6 | A2 | 70 | P1 | 30 | 30 | 0.50 | P1 | 25 | F1 |
| Film 7 | A1 | 70 | P1 | 30 | 30 | 0.48 | P1 | 25 | F1 |
| Film 8 | A1 | 70 | P1 | 30 | 30 | 0.48 | P1 | 25 | F1 |
| Film 9 | A1 | 65 | P1 | 35 | 25 | 0.55 | P1 | 25 | F1 |
| Film 10 | A1 | 30 | P1 | 70 | 30 | 1.00 | P1 | 25 | F1 |

| | Layer A | | | | | | |
|---|---|---|---|---|---|---|---|
| | Additive | | | | Elastic | | Dielectric |
| | Contents | | Film | | modulus | Copper | loss |
| | [% by | Mixing | thickness | Rc | at 160°c | foil | tangent of |
| | mass] | method | [μm] | [μm] | [MPa] | Type | film |
| Film 1 | 75 | A | 17 | 7 | 1.0 | M1 | 0.002 |
| Film 2 | — | A | 20 | 7 | 1.2 | M3 | 0.005 |
| Film 3 | — | — | 50 | 10 | 750 | M3 | 0.002 |
| Film 4 | 75 | A | 17 | 7 | 1.0 | M1 | 0.002 |
| Film 5 | 75 | B | 17 | 5.5 | 1.0 | M1 | 0.002 |
| Film 6 | 75 | A | 17 | 7 | 1.0 | M1 | 0.002 |
| Film 7 | 75 | A | 20 | 7 | 1.0 | M2 | 0.002 |
| Film 8 | 75 | A | 20 | 7 | 1.0 | M3 | 0.002 |
| Film 9 | 75 | A | 17 | 7 | 1.0 | M1 | 0.002 |
| Film 10 | 75 | A | 17 | 7 | 1.0 | M1 | 0.002 |

TABLE 2

| | | Elastic modulus [MPa] | | | | | |
|---|---|---|---|---|---|---|---|
| | | 25° C. | 40° C. | 100° C. | 160° C. | 230° C. | 260° C. |
| Material | A1 | 19 | 16 | 10 | 0.2 | 0.07 | 0.05 |
| a | A2 | 56 | 46 | 3 | 0.2 | 0.02 | 0.01 |
| Material | P1 | 2900 | 2100 | 1200 | 750 | 400 | 1.2 |
| b | | | | | | | |

From Table 2, it can be seen that, at 100° C. or lower, the elastic moduli of the material a and the material b are each 0.60 MPa or more.

At 160° C. or higher, it can be seen that the elastic modulus of the material a is less than 0.60 MPa and the elastic modulus of the material b is 0.60 MPa or more.

TABLE 3

| | Layer | | | | | | | |
|---|---|---|---|---|---|---|---|---|
| | configuration | | Laminate | | | | | |
| | | Copper | Step 1 | | Step 2 | | Step 3 | |
| | Film | foil | Temperature | Pressure | Temperature | Pressure | Temperature | Pressure |
| | Type | Type | [° C.] | [MPa] | [° C.] | [MPa] | [° C.] | [MPa] |
| Example 1 | Film 1 | M1 | 25 | 4 | 230 | 4 | 40 | 4 |
| Example 2 | Film 2 | M3 | 25 | 4 | 230 | 4 | 40 | 4 |
| Example 3 | Film 3 | M3 | 25 | 4 | 230 | 4 | 40 | 4 |
| Comparative | Film 3 | M3 | 230 | 0 | 230 | 4 | 40 | 4 |
| Example 1 | | | | | | | | |
| Example 4 | Film 4 | M1 | 25 | 4 | 230 | 4 | 40 | 4 |
| Example 5 | Film 4 | M1 | 25 | 2 | 230 | 2 | 40 | 2 |
| Example 6 | Film 4 | M1 | 25 | 2 | 230 | 1.8 | 40 | 1.8 |
| Example 7 | Film 4 | M1 | 25 | 4 | 160 | 4 | 40 | 4 |
| Example 8 | Film 4 | M1 | 25 | 4 | 230 | 4 | 25 | 4 |
| Comparative | Film 4 | M1 | 25 | 2 | 230 | 0.5 | 40 | 0.5 |
| Example 2 | | | | | | | | |
| Comparative | Film 4 | M1 | 25 | 4 | 100 | 4 | 40 | 4 |
| Example 3 | | | | | | | | |
| Comparative | Film 4 | M1 | 25 | 4 | 230 | 4 | 230 | 0 |
| Example 4 | | | | | | | | |
| Example 9 | Film 5 | M1 | 25 | 4 | 230 | 4 | 40 | 4 |
| Example 10 | Film 6 | M1 | 25 | 4 | 230 | 4 | 40 | 4 |
| Example 11 | Film 7 | M2 | 25 | 4 | 230 | 4 | 40 | 4 |
| Example 12 | Film 8 | M3 | 25 | 4 | 230 | 4 | 40 | 4 |
| Example 13 | Film 9 | M1 | 25 | 4 | 230 | 4 | 40 | 4 |
| Comparative | Film | M1 | 25 | 4 | 230 | 4 | 40 | 4 |
| Example 5 | 10 | | | | | | | |
| Example 14 | Film 4 | M1 | 25 | 2 | 230 | 1.8 | 40 | 1.8 |

| | | | Evaluation | | | |
|---|---|---|---|---|---|---|
| | | | of step | | | |
| | | | followability | | | |
| | | | Base | Base | | |
| | Laminate | | material | material | | |
| | Step 4 | | A with | B with | Peel | Evaluation of |
| | Temperature | Pressure | wiring | wiring | strength | heat |
| | [° C.] | [MPa] | patterns | patterns | [kN/m] | resistance |
| Example 1 | 40 | 0 | A | A | 0.8 | A |
| Example 2 | 40 | 0 | A | A | 0.8 | B |
| Example 3 | 40 | 0 | A | A | 0.8 | A |
| Comparative | 40 | 0 | A | A | 0.8 | D |
| Example 1 | | | | | | |
| Example 4 | 40 | 0 | A | A | 0.8 | A |
| Example 5 | 40 | 0 | A | A | 0.8 | A |
| Example 6 | 40 | 0 | A | A | 0.8 | B |
| Example 7 | 40 | 0 | A | A | 0.5 | B |
| Example 8 | 25 | 0 | A | A | 0.8 | A |
| Comparative | 40 | 0 | A | A | 0.8 | D |
| Example 2 | | | | | | |
| Comparative | 40 | 0 | A | A | 0.2 | D |
| Example 3 | | | | | | |
| Comparative | 40 | 0 | A | A | 0.8 | D |
| Example 4 | | | | | | |
| Example 9 | 40 | 0 | A | A | 0.8 | B |
| Example 10 | 40 | 0 | A | A | 0.6 | B |
| Example 11 | 40 | 0 | A | A | 0.8 | A |
| Example 12 | 40 | 0 | A | A | 0.8 | A |
| Example 13 | 40 | 0 | B | B | 0.6 | B |
| Comparative | 40 | 0 | D | D | 0.2 | C |
| Example 5 | | | | | | |
| Example 14 | 40 | 0 | A | A | 0.8 | A |

As shown in Table 3, in Examples 1 to 14, since the metal substrate disposing step, the pressurizing step, the heating step, the cooling step, and the unloading step are included in this order, the step followability and the heat resistance are excellent.

On the other hand, in Comparative Example 1, it was found that the heat resistance was poor because the step of pressurizing the material a and the material b at a temperature at which the elastic moduli of the material a and the material b were each 0.60 MPa or more was not performed.

In Comparative Example 2, it was found that the heat resistance was poor because the absolute value of the pressure change rate from Step 1 in Step 2 was more than 10%.

In Comparative Example 3, it was found that the heat resistance was poor because the heating temperature in Step 2 was a temperature at which the elastic modulus of the material a was 0.60 MPa or more.

In Comparative Example 4, it was found that the heat resistance was poor because the unloading was performed before cooling.

In Comparative Example 5, it was found that the step followability and the heat resistance were poor because the elastic modulus of the layer B of the polymer film at 160° C. was more than 0.60 MPa.

In Example 5, it was found that the heat resistance was excellent as compared with Example 6 because the pressure in Step 2 (heating step) was 2 MPa to 6 MPa.

In Example 4, it was found that the heat resistance was excellent as compared with Example 7 because the heating temperature in Step 2 (heating step) was 170° C. to 260° C.

In Example 4, it was found that the heat resistance was excellent as compared with Example 13 because the content of the material b was 10% by mass to 30% by mass with respect to the total mass of the layer B.

The disclosure of Japanese Patent Application No. 2023-108856 filed on Jun. 30, 2023 is incorporated in the present specification by reference. In addition, all documents, patent applications, and technical standards described in the present specification are incorporated herein by reference to the same extent as in a case of being specifically and individually noted that individual documents, patent applications, and technical standards are incorporated by reference.

What is claimed is:

1. A production method of a laminate, comprising, in the following order:
a step of disposing a metal substrate on at least one surface of a polymer film, the polymer film including a material a and a material b having different transition temperatures, including a layer B having an elastic modulus at 160° C. of 0.60 MPa or less, and having a dielectric loss tangent of 0.01 or less;
a step of pressurizing at a temperature at which elastic moduli of the material a and the material b are each 0.60 MPa or more;
a step of heating, at a pressure at which an absolute value of a pressure change rate from a pressure in the step of pressurizing is 10% or less, to a temperature at which the elastic modulus of the material a is less than 0.60 MPa and the elastic modulus of the material b is 0.60 MPa or more;
a step of cooling to a temperature at which the elastic modulus of the material a is 0.60 MPa or more; and
a step of unloading.

2. The production method of a laminate according to claim 1,
wherein a pressure in the step of heating is 2 MPa to 6 MPa.

3. The production method of a laminate according to claim 1,
wherein, in the step of heating, heating is performed to a temperature of 170° C. to 260° C.

4. The production method of a laminate according to claim 1,
wherein the polymer film further includes a layer A having an elastic modulus at 160° C. of more than 0.60 MPa, and
the production method further includes a step of manufacturing the polymer film by disposing the layer A and the layer B on at least one surface of the layer A.

5. The production method of a laminate according to claim 4,
wherein the step of manufacturing the polymer film further includes
a step of preparing a solution for forming a layer A by performing dispersion treatment with a bead mill, and
a step of forming a film by using the solution for forming a layer A and a solution for forming a layer B.

6. The production method of a laminate according to claim 1,
wherein the material a is an elastomer including a constitutional unit derived from styrene.

7. The production method of a laminate according to claim 1,
wherein the material a is at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

8. The production method of a laminate according to claim 1,
wherein the material b is at least one selected from the group consisting of a liquid crystal polymer, a polymerized substance of a compound having a cyclic aliphatic hydrocarbon group and a group having an ethylenically unsaturated bond, and a fluororesin.

9. The production method of a laminate according to claim 1,
wherein a content of the material b is 10% by mass to 30% by mass with respect to a total mass of the layer B.

10. A polymer film comprising:
a layer A; and
a layer B disposed on at least one surface of the layer A,
wherein a surface roughness Rc of a surface of the layer A on a side where the layer B is disposed is more than 5 μm,
the layer B contains a material a having an elastic modulus at 260° C. of less than 0.10 MPa and a material b having an elastic modulus at 260° C. of 0.10 MPa or more, and has an elastic modulus at 160° C. of 0.60 MPa or less, and
a dielectric loss tangent is 0.01 or less.

11. The polymer film according to claim 10,
wherein the layer A has an elastic modulus at 160° C. of more than 0.60 MPa.

12. The polymer film according to claim 10,
wherein the material a is an elastomer containing a constitutional unit derived from styrene.

13. The polymer film according to claim 10,
wherein the material a is at least one selected from the group consisting of a styrene-ethylene-butylene-styrene block copolymer, a styrene-isobutylene-styrene block copolymer, a styrene-ethylene-propylene-styrene copolymer, a styrene-isoprene-styrene block copolymer, and hydrogenated products thereof.

14. The polymer film according to claim 10,
wherein the material b is at least one selected from the group consisting of a liquid crystal polymer, a polymerized substance of a compound having a cyclic aliphatic hydrocarbon group and a group having an ethylenically unsaturated bond, and a fluororesin.

15. A laminate comprising:
the polymer film according to claim 10; and
a metal layer or a metal wiring disposed on at least one surface of the polymer film.

16. The laminate according to claim 15,
wherein the laminate includes the layer A, the layer B, and the metal layer or the metal wiring in this order, and
a peel strength between the layer B and the metal layer or the metal wiring is 0.3 kN/m or more.
